(19) United States
(12) Patent Application Publication
(10) Pub. No.: US 2025/0172696 A1
(43) Pub. Date: May 29, 2025

(54) CONTACTLESS BUTTON

(71) Applicant: DARWIN PRECISIONS CORPORATION, Hsinchu County (TW)

(72) Inventors: WEI CHEN, Hsinchu County (TW); chih-hung Liu, Hsinchu County (TW); SYUAN-WEI JHANG, Hsinchu County (TW)

(21) Appl. No.: 18/885,765

(22) Filed: Sep. 16, 2024

(30) Foreign Application Priority Data
Nov. 29, 2023 (TW) 112146347

(51) Int. Cl. G01S 17/04; H03K 17/94

(52) U.S. Cl. CPC G01S 17/04; H03K 17/941

(57) ABSTRACT

A contactless button includes a shell, a circuit board, a signal-transmitting element, a signal-sensing element, and a signal-blocking element. The shell has an opening. The circuit board is connected to the shell and has a surface facing the opening. The signal-transmitting element is electrically connected to the circuit board and is fixed to the surface. The signal-transmitting element is located in the shell and is adapted to emit a signal to the opening. The signal-sensing element is electrically connected to the circuit board and is fixed to the surface. The signal-sensing element is adapted to receive the signal reflected outside the shell. The signal-blocking element is arranged between the signal-transmitting element and the signal-sensing element.

### FIELD OF THE INVENTION

The present invention relates to a touch device, and particularly relates to a contactless button.

### BACKGROUND OF THE INVENTION

In general, a contactless button can be provided with a light source, a lens assembly, and an image layer. The light rays generated by the light source can form an image through the lens assembly and the image layer. The image can be suspended above the contactless button and can represent an operating message of the contactless button. Compared with a contact button, the contactless button has the advantages of being less prone to wear and easily maintained clean and the like. However, the assembling process of the conventional contactless button is complex, and therefore the contactless button still has defects of high cost, low yield, and the like.

### SUMMARY OF THE INVENTION

The present invention provides a contactless button with the advantages of low cost and high yield.

To achieve one or a portion of or all of the objects or other objects, the contactless button provided by the present invention includes a shell, a circuit board, a signal-transmitting element, a signal-sensing element, and a signal-blocking element. The shell has an opening. The circuit board is connected to the shell and has a surface facing the opening. The signal-transmitting element is electrically connected to the circuit board and is fixed to the surface. The signal-transmitting element is located in the shell and is adapted to emit a signal to the opening. The signal-sensing element is electrically connected to the circuit board and is fixed to the surface. The signal-sensing element is adapted to receive the signal reflected outside the shell. The signal-blocking element is arranged between the signal-transmitting element and the signal-sensing element.

In an embodiment of the present invention, the shell may further have a reflected signal inlet port, a transmission channel, and a reflected signal outlet port. The reflected signal inlet port, the transmission channel, and the reflected signal outlet port are connected to one another, and the reflected signal inlet port and the reflected signal outlet port are located on two opposite sides of the transmission channel. The reflected signal inlet port, the transmission channel, and the reflected signal outlet port are adapted to allow the signal reflected outside the shell to pass therethrough, and the reflected signal outlet port is adapted to emit the signal to the signal-sensing element.

In an embodiment of the present invention, the shell further has, for example, a body portion and a cover frame portion. The body portion is connected to the surface and has an accommodating space. The signal-transmitting element is located in the accommodating space. The cover frame portion is connected to the body portion and is opposite to the circuit board. The opening passes through the cover frame portion and is communicated to the accommodating space. The reflected signal inlet port, the transmission channel, and the reflected signal outlet port pass through the cover frame portion, and the reflected signal inlet port faces the opening.

In an embodiment of the present invention, the aforementioned contactless button may further include a signal-conducting element. The signal-conducting element is arranged in the transmission channel and has a signal inlet port and a signal outlet port. The signal inlet port is close to the signal outlet port, and the signal inlet port is close to the reflected signal outlet port.

In an embodiment of the present invention, the signal-conducting element includes a light guide pillar. The signal inlet port includes a light-incident surface of the light guide pillar, and the signal outlet port includes a light-emitting surface of the light guide pillar. An area of the light-incident surface is smaller than an area of the light-emitting surface.

In an embodiment of the present invention, the light-incident surface protrudes, for example, from the reflected signal inlet port.

In an embodiment of the present invention, the light-emitting surface protrudes, for example, from the reflected signal outlet port.

In an embodiment of the present invention, the contactless button further includes, for example, a cylinder. The cylinder is fixed to the surface, and the signal-sensing element is located in the cylinder. The cylinder has a first side wall and a second side wall. The first side wall and the second side wall are connected to each other and encircle the signal-sensing element. The first side wall is located between the signal-transmitting element and the signal-sensing element, and the signal-blocking element includes the first side wall.

In an embodiment of the present invention, the cylinder further has an inner surface, and the inner surface extends to the second side wall from the first side wall. The inner surface can include a light reflective material.

In an embodiment of the present invention, the signal-blocking element and the shell form an integrated structure or a separated structure.

In an embodiment of the present invention, the signal-blocking element is fixed to the surface, and the signal-blocking element is in a shape of a plate.

In an embodiment of the present invention, the signal-transmitting element includes, for example, an infrared signal-transmitting element, and the signal includes an infrared ray. The signal-sensing element can include an infrared-sensing element.

In the contactless button of the present invention, the signal-transmitting element and the signal-sensing element both are fixed to and electrically connected to the same circuit board. Therefore, the signal-sensing element is fixed to and electrically connected to the circuit board by a primary connecting and fixing step. Therefore, the step of dispensing and fixing the signal-sensing element can be omitted, and the electric wire that electrically connects the signal-sensing element to the circuit board can also be omitted so that the step of welding the electric wire can further be saved. In addition, because the signal-sensing element is directly electrically connected to the circuit board rather than being electrically connected to the circuit board via the electric wire, poor induction of the contactless button as the electric wire is pulled can also be prevented. Based on the above, the contactless button provided by the present invention can have the advantages of low cost and high yield.

Other objectives, features and advantages of the invention will be further understood from the further technological features disclosed by the embodiments of the invention wherein there are shown and described preferred embodiments of this invention, simply by way of illustration of modes best suited to carry out the invention.

### BRIEF DESCRIPTION OF THE DRAWINGS

FIG. 1 is a cross-sectional view of a contactless button in an embodiment of the present invention;

FIG. 2 is a schematic top view of the contactless button in FIG. 1 without a cover frame portion;

FIG. 3 is a schematic top view of the contactless button in FIG. 2;

FIG. 4 is a cross-sectional view of a contactless button in another embodiment of the present invention;

FIG. 5 is a schematic top view of the contactless button in FIG. 4;

FIG. 6 is a cross-sectional view of a contactless button in another embodiment of the present invention;

FIG. 7 is a three-dimensional schematic diagram of a signal-conducting element in FIG. 6;

FIG. 8 is a cross-sectional view of a contactless button in another embodiment of the present invention; and

FIG. 9 is a cross-sectional view of the contactless button in another embodiment of the present invention.

### DETAILED DESCRIPTION OF PREFERRED EMBODIMENTS

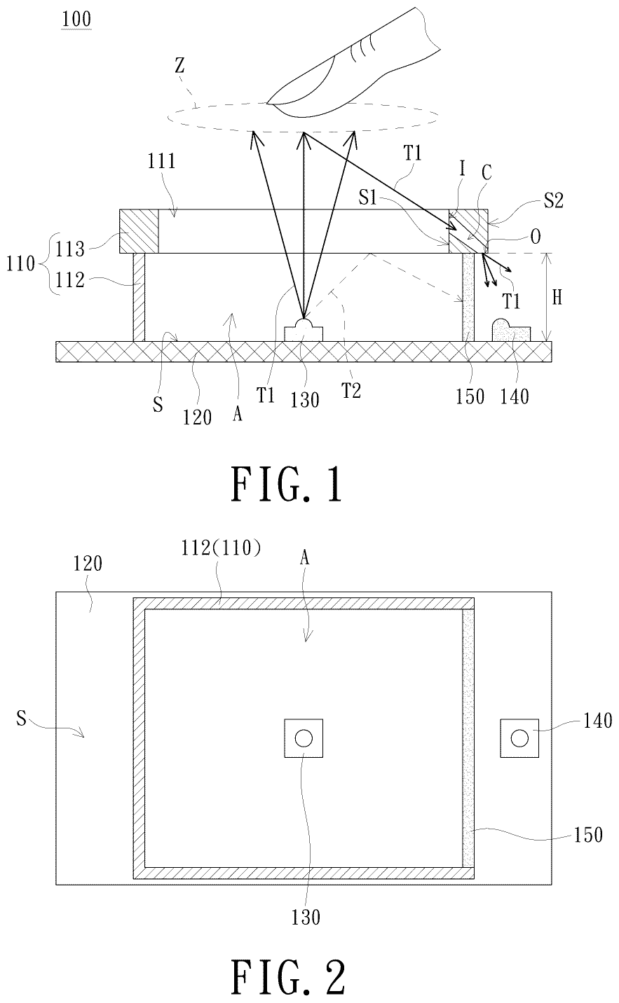

FIG. 1 is a cross-sectional view of a contactless button in an embodiment of the present invention. FIG. 2 is a schematic top view of the contactless button in FIG. 1 without a cover frame portion. Referring to FIG. 1 and FIG. 2, a contactless button 100 includes a shell 110, a circuit board 120, a signal-transmitting element 130, a signal-sensing element 140, and a signal-blocking element 150. The shell 110 has an opening 111. The circuit board 120 is connected to the shell 110 and has a surface S facing the opening 111. The signal-transmitting element 130 is electrically connected to the circuit board 120 and is fixed to the surface S. The signal-transmitting element 130 is located in the shell 110 and is adapted to emit a signal T1 to the opening 111. The signal-sensing element 140 is electrically connected to the circuit board 120 and is fixed to the surface S. The signal-sensing element 140 is adapted to receive the signal T1 reflected outside the shell 110. The signal-blocking element 150 is arranged between the signal-transmitting element 130 and the signal-sensing element 140.

The signal-transmitting element 130 can emit signals T1 and T2, where the signal T1 can be emitted from the opening 111 and can be reflected by an object outside the shell 110 to be incident to the signal-sensing element 140. For example, the signal T1 can form a touch area Z above the opening 111, and a user can make a finger close to the touch area Z to reflect the signal T1 to the signal-sensing element 140. On the other hand, the signal T2 is left in the shell 110 and is not emitted from the opening 111. In the embodiment, the signal-transmitting element 130 includes, for example, an infrared signal-transmitting element, and the signals T1 and T2 can include an infrared ray, but other embodiments are not limited thereto.

The signal-sensing element 140 can receive the signal T1 sent by the signal-transmitting element 130 and can generate a sensing signal after receiving the signal T1 to drive other electronic components to operate. For example, the signal-sensing element 140 can transmit the sensing signal to the light source to drive the light source to emit light. In an embodiment, the signal-sensing element 140 can transmit the sensing signal to a speaker to drive the speaker to output a sound. The light source and the speaker can be electrically connected to the circuit board 120 to receive the sensing signal from the signal-sensing element 140 via the circuit board 120. However, the present invention does not limit the type and specific details of the aforementioned electronic components. In the embodiment, the signal-sensing element 140 can include an infrared-sensing element, but the present invention is not limited thereto.

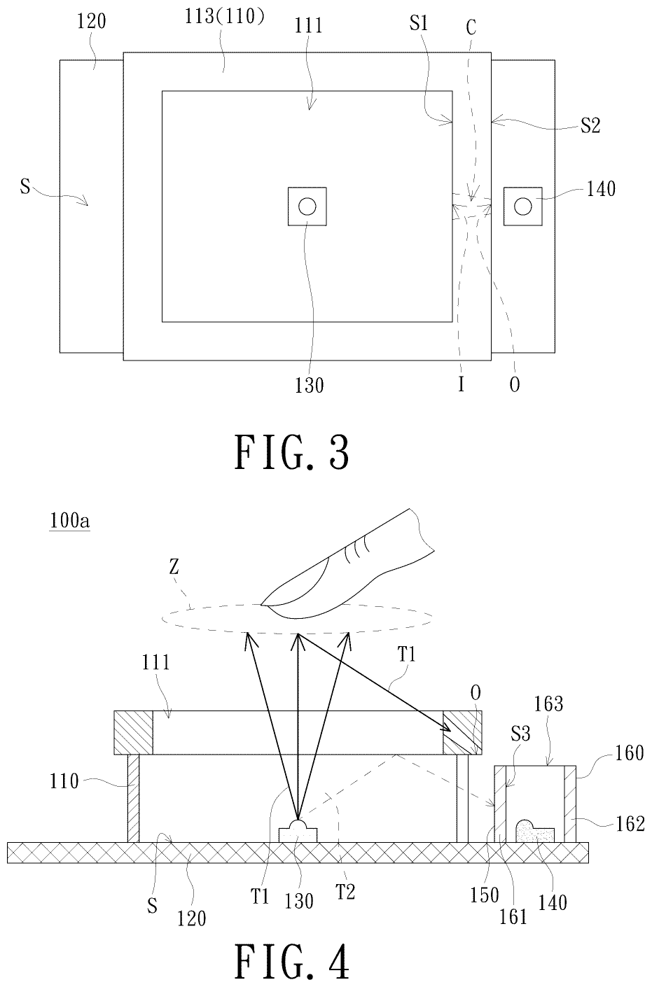

FIG. 3 is a schematic top view of the contactless button in FIG. 2. Referring to FIG. 1 and FIG. 3, the shell 110 can be fixed to the surface S of the circuit board 120 to accommodate the signal-transmitting element 130. In the embodiment, the shell 110 can further have a reflected signal inlet port I, a transmission channel C, and a reflected signal outlet port O. The reflected signal inlet port I, the transmission channel C, and the reflected signal outlet port O are connected one another, and the reflected signal inlet port I and the reflected signal outlet port O are located on two opposite sides of the transmission channel C. The reflected signal inlet port I, the transmission channel C, and the reflected signal outlet port O are adapted to allow the signal T1 reflected outside the shell 110 to pass therethrough, and the reflected signal outlet port O is adapted to emit the signal T1 to the signal-sensing element 140. In detail, the signal T1 reflected outside the shell 110 can be guided by the reflected signal inlet port I, the transmission channel C, and the reflected signal outlet port O to be incident into the signal-sensing element 140 in a more concentrated manner, so that the quantity of signals incident into the signal-sensing element 140 is increased. Thus, the touch area Z can be farther away from the opening 111, that is, the user can trigger the signal-sensing element 140 at a position farther away from the opening 111, so that the induction sensitivity of the signal-sensing element 140 is improved.

Continuously referring to FIG. 1, the shell 110 further has, for example, a body portion 112 (also shown in FIG. 2) and a cover frame portion 113 (also shown in FIG. 3). The body portion 112 is connected to the surface S and has an accommodating space A. The signal-transmitting element 130 is located in the accommodating space A. The cover frame portion 113 is connected to the body portion 112 and is opposite to the circuit board 120. The opening 111 passes through the cover frame portion 113 and is communicated to the accommodating space A. The reflected signal inlet port I, the transmission channel C, and the reflected signal outlet port O pass through the cover frame portion 113, and the reflected signal inlet port I faces the opening 111. Further, the reflected signal inlet port I is, for example, located on an inner side surface S1 (also shown in FIG. 3) of the cover frame portion 113, the reflected signal outlet port O can be located on an outer side surface S2 (also shown in FIG. 3) of the cover frame portion 113, and the transmission channel C can pass through the inner side surface S1 and the outer side surface S2. In addition, the reflected signal outlet port O can substantially face the signal-sensing element 140. In detail, the reflected signal inlet port I is, for example, communicated to the opening 111, and the signal T1 reflected outside the shell 110 can enter the reflected signal inlet port I through the opening 111 and is emitted from the reflected signal outlet port O to the signal-sensing element 140 through the transmission channel C. Incidentally, the body portion 112 and the cover frame portion 113 can form a separated structure, that is, the cover frame portion 113 can be detached from the body portion 112. Therefore, the position of the reflected signal outlet port O can be more easily adjusted by fitting the signal-sensing element 140 so the assembling flexibility of the contactless button 100 is improved.

Referring to FIG. 1 and FIG. 2 again, the signal-blocking element 150 can block the signal T2 in the shell 110 from being incident into the signal-sensing element 140. Specifically, the signal T2 sent by the signal-transmitting element 130 is not emitted from the opening 111 and is left in the shell 110 to be reflected back and forth. The signal-blocking element 150 can prevent the signal T2 in the shell 110 from being directly incident into the signal-sensing element 140 to prevent the signal T2 from mis-inducing the signal-sensing element 140. In the embodiment, the signal-blocking element 150 is fixed to the surface S, and the signal-blocking element 150 can be in the shape of a plate. In detail, the signal-blocking element 150 can be connected to the body portion 112. However, in an embodiment, the signal-blocking element 150 can be slightly separated from the body portion 112. In addition, the present invention does not limit the height H of the signal-blocking element 150. For example, the signal-blocking element 150 in the embodiment can be connected to the cover frame portion 113. However, in another embodiment, the signal-blocking element 150 can be slightly separated from the cover frame portion 113. In addition, the signal-blocking element 150 and the shell 110 are of a split structure. For example, the signal-blocking element 150, the body portion 112 and the cover frame portion 113 can be detached respectively. However, in an embodiment, the signal-blocking element 150 and the shell 110 are of an integrated structure. Further, the signal-blocking element 150 and the body portion 112 can form an integrated structure, and the signal-blocking element 150 and the cover frame portion 113 can form a separated structure. In another embodiment, the signal-blocking element 150 and the cover frame portion 113 can form an integrated structure, and the signal-blocking element 150 and the body portion 112 can form a separated structure, but the present invention is not limited thereto.

In the embodiment, the circuit board 120 can transmit electric power to the signal-transmitting element 130 and the signal-sensing element 140. The circuit board 120 includes, for example, a printed circuit board (PCB), where the PCB can include a single-layer PCB, a double-layer PCB, and a multi-layer PCB, but the present invention is not limited thereto. In the embodiment, because the signal-transmitting element 130 and the signal-sensing element 140 are fixed to and electrically connected to the same circuit board 120, the assembling process of the signal-sensing element 140 can be effectively simplified.

For example, in the prior art, the signal-sensing element can be eclectically connected to the same circuit board with the signal-transmitting element at least through steps of connecting and fixing, electric wire welding, and the like. In addition, the electric power and the signals of the signal-sensing element are transmitted via the electric wire and the electric wire is poor in contact as it is pulled in the subsequent assembling process, resulting in not only a tedious assembling process of the known contactless button but also easily occurred poor induction. Further, in the prior art, the electric wire needs to be further fixed and protected by steps of dispensing, tape coating, and the like. Thus, the assembling process of the contactless button is more tedious, and the problem of poor contact with the electric wire cannot be completely solved. On the contrary, in the embodiment, the signal-sensing element 140 can be assembled to the circuit board 120 by the primary connecting and fixing step, so the materials such as the electric wire are omitted. Therefore, in the assembling process of the contactless button 100, the steps of welding the electric wire, dispensing, tape coating, and the like can be omitted, and the problem of poor induction of the signal-sensing element 140 caused by the electric wire can also be solved.

Compared with the prior art, in the contactless button 100 in the embodiment, the signal-transmitting element 130 and the signal-sensing element 140 both are fixed to and electrically connected to the same circuit board 120. Therefore, the signal-sensing element 140 can be fixed to and electrically connected to the circuit board 120 by the primary connecting and fixing step. Therefore, the step of dispensing and fixing the signal-sensing element 140 can be omitted, and the electric wire that electrically connects the signal-sensing element 140 to the circuit board 120 can also be omitted so that a step of welding the electric wire can further be saved. In addition, because the signal-sensing element 140 is directly electrically connected to the circuit board 120 rather than being electrically connected to the circuit board 120 via the electric wire, poor induction of the contactless button 100 as the electric wire is pulled can also be prevented. Based on the above, the contactless button 100 in the embodiment can have the advantages of low cost and high yield.

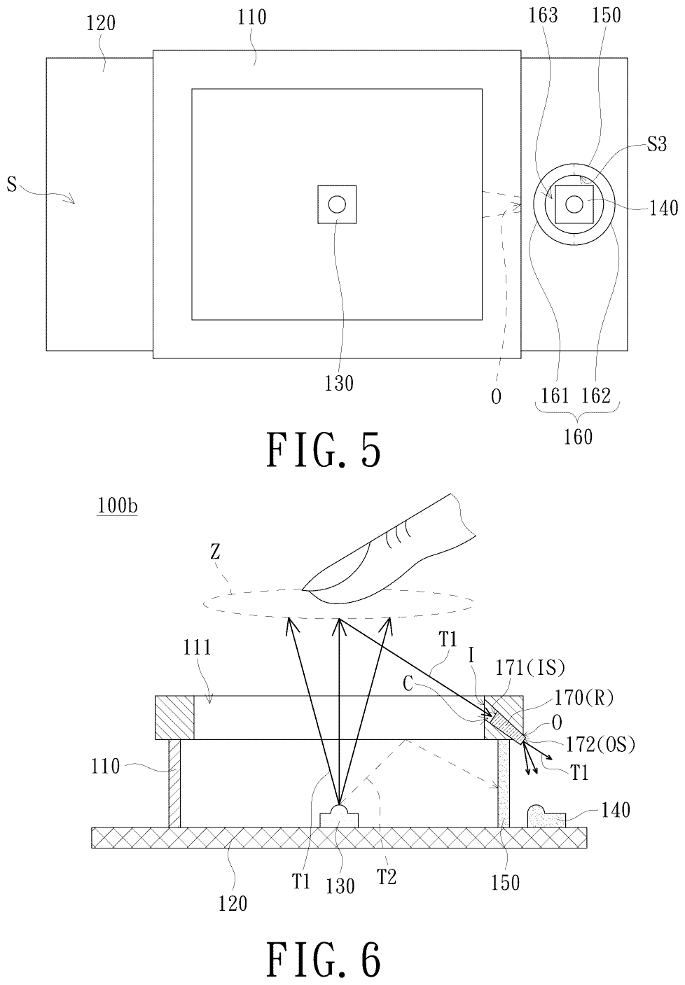

FIG. 4 is a cross-sectional view of a contactless button in another embodiment of the present invention. FIG. 5 is a schematic top view of the contactless button in FIG. 4. The structure and advantages of the contactless button 100a in the embodiment are similar to those in the embodiment shown in FIG. 1, and only the differences will be described below. Referring to FIG. 4 and FIG. 5, the contactless button 100a further includes, for example, a cylinder 160. The cylinder 160 is fixed to the surface S, and the signal-sensing element 140 is located in the cylinder 160. Specifically, the signal T1 entering the cylinder 160 can be reflected in the cylinder 160 many times to be incident into the signal-sensing element 140, so the quantity of signals received by the signal-sensing element 140 is increased, and therefore, the touch area Z can be farther away from the opening 111.

It is to be noted that the cylinder 160 can further serve as the signal-blocking element 150. In detail, the cylinder 160 has a first side wall 161 and a second side wall 162. The first side wall 161 and the second side wall 162 are connected to each other and encircle the signal-sensing element 140. The first side wall 161 is located between the signal-transmitting element 130 and the signal-sensing element 140, and the signal-blocking element 150 includes the first side wall 161. Simply speaking, the first side wall 161 can prevent the signal T2 in the shell 110 from being incident into the signal-sensing element 140, so as to prevent the signal T2 from mis-inducing the signal-sensing element 140. Therefore, the first side wall 161 can serve as the signal-blocking element 150. Incidentally, the first side wall 161 and the second side wall 162 may, for example, form an integrated structure. But in an embodiment, the first side wall 161 and the second side wall 162 may form a separated structure. In the embodiment, the cylinder 160 is, for example, cylindrical. The first side wall 161 and the second side wall 162 are, for example, arc-shaped side walls. However, in other embodiments, the cylinder 160 can be squarely cylindrical or polygonally cylindrical, but the present invention is not limited thereto.

Incidentally, the cylinder 160 in the embodiment further has an inner surface S3, and the inner surface S3 extends to the second side wall 162 from the first side wall 161. The inner surface S3 can include a light reflective material to increase the quantity of signals received by the signal-sensing element 140. For example, the aforementioned light reflective material can include a metal or white material, but the present invention is not limited thereto. Incidentally, the opening 163 of the cylinder 160 can be close to the reflected signal outlet port O so more signals T1 can be incident into the cylinder 160.

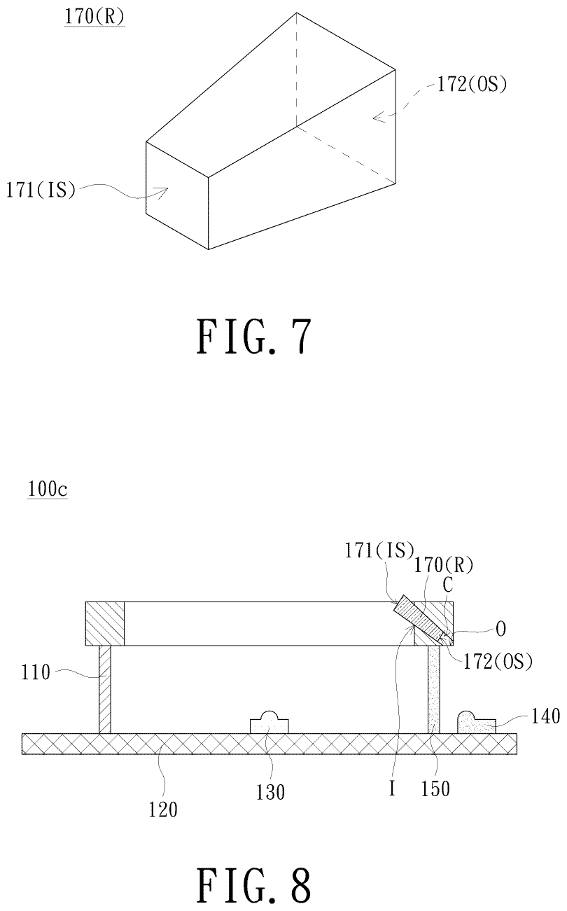

FIG. 6 is a cross-sectional view of a contactless button in another embodiment of the present invention. FIG. 7 is a schematic three-dimensional diagram of a signal-conducting element in FIG. 6. The structure and advantages of the contactless button 100b in the embodiment are similar to those in the embodiment shown in FIG. 1, and only the differences will be described below. Referring to FIG. 6 and FIG. 7, the contactless button 100b can further include a signal-conducting element 170. The signal-conducting element 170 is arranged in the transmission channel C and has a signal inlet port 171 and a signal outlet port 172. The signal inlet port 171 is close to the reflected signal inlet port I, and the signal outlet port 172 is close to the reflected signal outlet port O. Therefore, the signal-conducting element 170 can guide the signal T1 to be incident into the signal-sensing element 140 so the quantity of signals received by the signal-sensing element 140 is increased, and therefore, the touch area Z can be farther away from the opening 111. For example, the signal-conducting element 170 includes a light guide pillar R. The signal inlet port 171 includes a light-incident surface IS of the light guide pillar R, and the signal outlet port 172 includes a light-emitting surface OS of the light guide pillar R. The area of the light-incident surface IS is smaller than the area of the light-emitting surface OS so the signal T1 can be incident into the signal-sensing element 140 in a more concentrated manner. In detail, the signals T1 and T2 in the embodiment can include an infrared ray, and the light guide pillar R can gather the infrared ray to the signal-sensing element 140. Incidentally, the light-emitting surface OS can protrude out from the reflected signal outlet port O. Therefore, the light guide pillar R can more easily emit the signal to the signal-sensing element 140, so that the quantity of signals received by the signal-sensing element 140 is further increased.

FIG. 8 is a cross-sectional view of a contactless button in another embodiment of the present invention. The structure and advantages of the contactless button 100c in the embodiment are similar to those in the embodiment shown in FIG. 6, and only the differences will be described below. Referring to FIG. 8, the light-incident surface IS can protrude, for example, from the reflected signal inlet port I to increase the quantity of signals entering the light guide pillar R, so the quantity of signals received by the signal-sensing element 140 is further increased. It can be understood that in an embodiment, the light-incident surface IS can protrude from the reflected signal inlet port I, and the light-emitting surface OS can protrude from the reflected signal outlet port O. In other words, the light-incident surface IS and the light-emitting surface OS both protrude from the shell 110. In another embodiment, the light-incident surface IS may not protrude out from the reflected signal inlet port I, and the light-emitting surface OS may not protrude out from the reflected signal outlet port O. In other words, the light guide pillar R can be completely located in the transmission channel C.

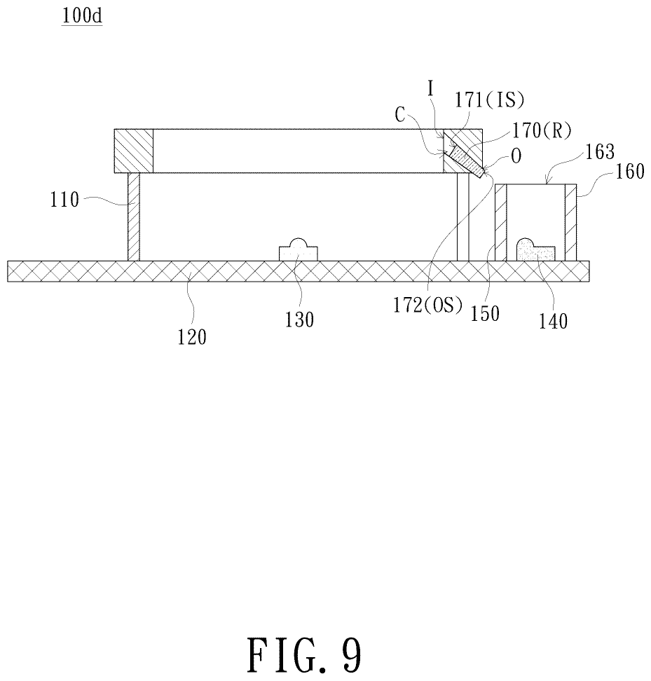

FIG. 9 is a cross-sectional view of a contactless button in another embodiment of the present invention. Incidentally, although the light guide pillars R in FIG. 6 and FIG. 8 both are provided in the embodiment of FIG. 1, other embodiments are not limited thereto. For example, referring to the contactless button 100d in FIG. 9, the light guide pillar R can be provided in the embodiment in FIG. 4. In detail, the light-emitting surface OS can protrude from the reflected signal outlet port O, so the light-emitting surface OS can be closer to the opening 163 of the cylinder 160, and therefore, the quantity of signals entering the cylinder 160 is increased. Other characteristics of the light guide pillar R are similar to those in the embodiments of FIG. 6 and FIG. 8, and no redundant detail is to be given herein.

In summary, in the contactless button of the present invention, the signal-transmitting element and the signal-sensing element both are fixed to and electrically connected to the same circuit board. Therefore, the signal-sensing element is fixed to and electrically connected to the circuit board by a primary connecting and fixing step. Therefore, the step of dispensing and fixing the signal-sensing element can be omitted, and an electric wire that electrically connects the signal-sensing element to the circuit board can also be omitted so that the step of welding the electric wire can further be saved. In addition, because the signal-sensing element is directly electrically connected to the circuit board rather than being electrically connected to the circuit board via the electric wire, poor induction of the contactless button as the electric wire is pulled can also be prevented. Based on the above, the contactless button provided by the present invention can have the advantages of low cost and high yield.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation to encompass all such modifications and similar structures.

What is claimed is:

1. A contactless button, comprising:
a shell, having an opening;
a circuit board, connected to the shell and having a surface facing the opening;
a signal-transmitting element, electrically connected to the circuit board and fixed to the surface, wherein the signal-transmitting element is located in the shell and is adapted to emit a signal toward the opening;
a signal-sensing element, electrically connected to the circuit board and fixed to the surface, wherein the signal-sensing element is adapted to receive the signal reflected outside the shell; and
a signal-blocking element, arranged between the signal-transmitting element and the signal-sensing element.

2. The contactless button according to claim 1, wherein the shell further has a reflected signal inlet port, a transmission channel, and a reflected signal outlet port, the reflected signal inlet port, the transmission channel, and the reflected signal outlet port are communicated with one another, the reflected signal inlet port and the reflected signal outlet port are located on two opposite sides of the transmission channel, the reflected signal inlet port, the transmission channel, and the reflected signal outlet port are adapted to allow the signal reflected outside the shell to pass therethrough, and the reflected signal outlet port is adapted to emit the signal toward the signal-sensing element.

3. The contactless button according to claim 2, wherein the shell further has a body portion and a cover frame portion, the body portion is connected to the surface and has an accommodating space, the signal-transmitting element is located in the accommodating space, the cover frame portion is connected to the body portion and is opposite to the circuit board, the opening passes through the cover frame portion and is communicated to the accommodating space, the reflected signal inlet port, the transmission channel, and the reflected signal outlet port pass through the cover frame portion, and the reflected signal inlet port faces the opening.

4. The contactless button according to claim 2, further comprising a signal-conducting element, wherein the signal-conducting element is arranged in the transmission channel and has a signal inlet port and a signal outlet port, the signal inlet port is close to the signal outlet port, and the signal outlet port is close to the reflected signal outlet port.

5. The contactless button according to claim 4, wherein the signal-conducting element comprises a light guide pillar, the signal inlet port comprises a light-incident surface of the light guide pillar, the signal outlet port comprises a light-emitting surface of the light guide pillar, and an area of the light-incident surface is less than an area of the light-emitting surface.

6. The contactless button according to claim 5, wherein the light-incident surface protrudes out from the reflected signal inlet port.

7. The contactless button according to claim 5, wherein the light-emitting surface protrudes from the reflected signal outlet port.

8. The contactless button according to claim 1, further comprising a cylinder, wherein the cylinder is fixed to the surface, the signal-sensing element is located in the cylinder, the cylinder has a first side wall and a second side wall, the first side wall and the second side wall are connected to each other and encircle the signal-sensing element, the first side wall is located between the signal-transmitting element and the signal-sensing element, and the signal-blocking element comprises the first side wall.

9. The contactless button according to claim 8, wherein the cylinder further has an inner surface, the inner surface extends to the second side wall from the first side wall, and the inner surface comprises a light reflective material.

10. The contactless button according to claim 1, wherein the signal-blocking element and the shell form an integrated structure or a separated structure.

11. The contactless button according to claim 1, wherein the signal-blocking element is fixed to the surface, and the signal-blocking element is in a shape of a plate.

12. The contactless button according to claim 1, wherein the signal-transmitting element comprises an infrared signal-transmitting element, the signal comprises an infrared ray, and the signal-sensing element comprises an infrared-sensing element.
